(19) United States
(12) Patent Application Publication
(10) Pub. No.: US 2005/0160988 A1
(43) Pub. Date: Jul. 28, 2005

(54) Semiconductor-producing apparatus

(75) Inventors: Kenji Shinma, Itami-shi (JP); Hirohiko Nakata, Itami-shi (JP); Masuhiro Natsuhara, Itami-shi (JP)

Correspondence Address: MCDERMOTT WILL & EMERY LLP, 600 13TH STREET, N.W., WASHINGTON, DC, 20005-3096, US

(73) Assignee: SUMITOMO ELECTRIC INDUSTRIES LTD.

(21) Appl. No.: 11/029,408

(22) Filed: Jan. 6, 2005

(30) Foreign Application Priority Data
Jan. 22, 2004 (JP) 013736/2004

(51) Int. Cl. C23C 16/00

(52) U.S. Cl. 118/725

(57) ABSTRACT

A semiconductor-producing apparatus increases both the cooling rate of the heater and the uniformity in the temperature distribution of the heater. The semiconductor-producing apparatus of the present invention is provided with a heater for heat-treating a semiconductor wafer and a cooling block for cooling the heater. The cooling block is provided with at least one through hole for inserting a penetrating object. The distance from the inner surface of the or each through hole to the penetrating object is at most 50 mm. The cooling block is arranged such that it can both make contact with and separate from the heater's face opposite to the face for placing the wafer. The foregoing penetrating object is a current-feeding electrode for feeding current to the heater circuit, a temperature-measuring means, or the like.

### BACKGROUND OF THE INVENTION

1. Field of the Invention

The present invention relates to a semiconductor-producing apparatus that is provided with a heater for heating a wafer placed on it to perform an intended treatment and with a cooling block for cooling the heater and that can be applied to the following apparatuses: an etching device, a sputtering device, a plasma CVD unit, a reduced-pressure plasma CVD unit, a metal CVD unit, an insulating-film CVD unit, a low-dielectric-constant-film (Low-K) CVD unit, an MOCVD unit, a degasifier, an ion implanter, a coater-developer, and so on.

2. Description of the Background Art

As a usual practice, in the process for producing a semiconductor, a material to be treated such as a semiconductor substrate (wafer) is subjected to various treatments including film formation and etching. A semiconductor-producing apparatus for performing such treatments of a semiconductor substrate is provided with a ceramic heater for supporting and heating the substrate.

For example, in the step of photolithography, a pattern of a resist film is formed on the wafer. In this step, first, the wafer is rinsed and dried by heating. After it is cooled down, a resist material is applied onto the surface of the wafer to form a resist film. The wafer is placed on the ceramic heater in an apparatus for performing the photolithographic treatment. After the resist film is dried, treatments such as exposure and development are conducted. In this step of photolithography, the quality of the formed film is dependent largely on the temperature for drying the resist film. Consequently, the uniformity in the temperature of the ceramic heater at the time of the treatment is important.

For another example, in the CVD step, after the wafer is rinsed and dried, it is placed on the ceramic heater in the CVD equipment. An insulating film and a metallic film are formed on the surface of the wafer by chemical reaction. The quality of the formed insulating and metallic films is dependent largely on the temperature at the time of the chemical reaction. Consequently, in this case also, the uniformity in the temperature of the ceramic heater is important.

On the other hand, these wafer treatments are required to complete in the shortest possible time to increase the throughput. To meet this requirement, a semiconductor-producing apparatus is devised that is provided with a cooling means capable of cooling a hot heater in a short time. For example, the published Japanese patent application Tokukaihei 06-346256 has disclosed a semiconductor-producing apparatus that is provided with a heater in which a coolant-flowing path is formed to feed a cooling gas.

In addition, another published Japanese patent application, Tokukai 2004-014655, has proposed a semiconductor-producing apparatus that is provided with a cooling block capable of both making contact with and separating from the heater's face opposite to the face for placing the wafer.

The technique proposed in the foregoing Tokukai 2004-014655 can increase the cooling rate of the heater dramatically by bringing the cooling block into contact with the heater when the heater is cooled. However, it turned out that the provision of the cooling block causes the temperature distribution of the heater to be nonuniform. Depending on the application, the nonuniformity in the temperature distribution of the heater poses a problem. As a result, the technique proposed in the foregoing Tokukai 2004-014655 has been limited to the application that does not require high uniformity in the temperature distribution of the heater.

### SUMMARY OF THE INVENTION

In view of the above-described problems, an object of the present invention is to offer a semiconductor-producing apparatus in which not only is the cooling rate of the heater increased but also the uniformity in the temperature distribution of the heater is increased. Such a semiconductor-producing apparatus can be used in a wider range of application.

To achieve the above-described object, the present invention offers a semiconductor-producing apparatus that is provided with a heater for heat-treating a semiconductor wafer and a cooling block for cooling the heater. The cooling block is provided with at least one through hole for inserting a penetrating object. The distance from the inner surface of the or each through hole to the penetrating object is at most 50 mm. The cooling block is arranged such that it can both make contact with and separate from the heater's face opposite to the face for placing the wafer. The foregoing penetrating object is a current-feeding electrode for feeding current to the heater circuit, a temperature-measuring means, or the like.

The cooling block may have a distance of at least 0.1 mm from the inner surface of the or each through hole to the penetrating object. In this case, the uniformity of the temperature distribution of the heater is further increased.

The cooling block may be made of a material having a thermal conductivity of at least 30 W/mK. It may also be made of a material having a thermal conductivity of at least 100 W/mK.

The heater's major constituent may be any one of aluminum nitride, aluminum oxide, silicon carbide, and silicon nitride. In particular, the heater's major constituent may be aluminum nitride.

The present invention enables the production of a semiconductor-producing apparatus provided with a heater that has not only a dramatically increased cooling rate, which is achieved by bringing the cooling block into contact with the heater when the heater is cooled, but also an excellent uniformity in temperature distribution. Consequently, when the semiconductor-producing apparatus of the present invention is applied to the following various semiconductor-producing apparatuses, the apparatuses can have a sufficient temperature distribution: an etching device, a sputtering device, a plasma CVD unit, a reduced-pressure plasma CVD unit, a metal CVD unit, an insulating-film CVD unit, a low-dielectric-constant-film CVD unit, an MOCVD unit, a degasifier, an ion implanter, a coater-developer, and so on.

### BRIEF DESCRIPTION OF THE DRAWINGS

In the drawing:

FIG. 1 is a schematic cross-sectional view showing an example of the semiconductor-producing apparatus of the present invention.

FIG. 2 is a schematic cross-sectional view showing the semiconductor-producing apparatus shown in FIG. 1 when the cooling block is in contact with the heater.

FIG. 3 is a schematic cross-sectional view showing another example of the semiconductor-producing apparatus of the present invention.

### DETAILED DESCRIPTION OF THE INVENTION

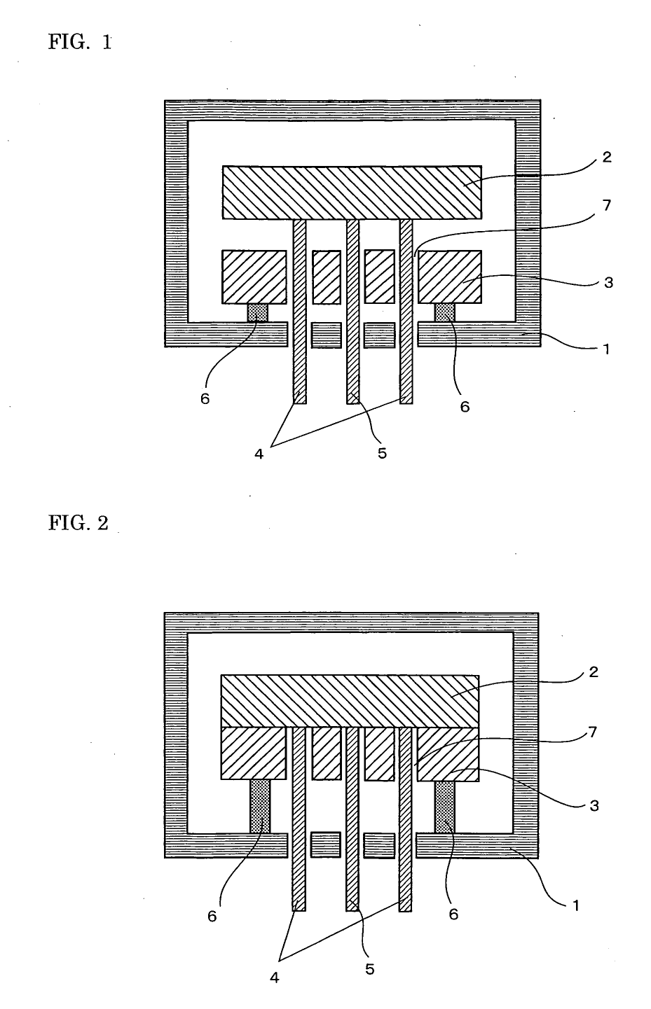

The present inventors studied the cause of the nonuniformity in the temperature distribution of the heater in the technique proposed in the foregoing Tokukai 2004-014655. The study revealed that when the distance from the inner surface of the through hole of the cooling block to the penetrating object is excessively large, the temperature distribution of the heater becomes nonuniform. An embodiment of the present invention is explained below by referring to FIG. 1. FIG. 1 shows an example of the embodiment of the present invention. A semiconductor-producing apparatus is provided with a heater 2 and a cooling block 3 in a container 1. Current-feeding electrodes 4 for feeding current to the heater circuit and a temperature-measuring means 5 such as a thermocouple or a temperature-measuring resistor are connected to the heater 2. The current-feeding electrodes and temperature-measuring means are drawn out of the container 1 to be connected to a temperature-controlling unit (not shown).

The cooling block 3 is placed in the container 1 through an ascending and descending means 6 such as an air cylinder. The cooling block 3 can both make contact with and separate from the heater 2 as required. FIG. 1 shows a state when the cooling block 3 is separated from the heater 2, and FIG. 2 when the cooling block 3 is in contact with the heater 2. The cooling block 3 is provided with through holes 7 for allowing the penetrating objects such as the foregoing electrodes and temperature-measuring means to pass through.

When the cooling block 3 is separated from the heater 2, if the distance from the inner surface of the through holes 7 to the penetrating objects 4 and 5, such as the electrodes and temperature-measuring means, is excessively large, the gas flowing out or in through the through holes 7 causes a reduction in the uniformity in the temperature distribution of the heater 2.

For example, when the heater 2 is maintained at high temperature, the gas in the container 1 is heated by the heater 2 and convection of the gas is generated in the container. The convective current ascends from the heater 2, arrives at the ceiling of the container, descends from the ceiling along the surface of the wall while it is cooled, turns to the underside of the cooling block 3, and ascends in the through holes 7 of the cooling block 3. The gas outside the container enters through the through holes of the container in such a manner that the gas is dragged into the current. The gas outside the container has a temperature lower than that of the heater 2. Consequently, when the gas from the outside makes contact with the heater 2, the temperature of the heater 2 decreases locally, reducing the uniformity in the temperature distribution of the heater 2.

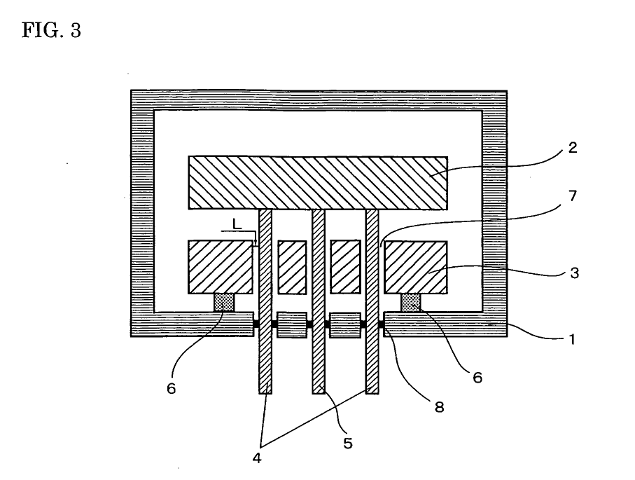

As shown in FIGS. 1 and 2, the container 1 has a structure that allows gas to enter and exit the container 1. FIG. 3 shows a structure that prevents the gas from entering and exiting the container 1 by sealing the container 1 using a sealing material 8. Even when this structure is employed, if the distance from the inner surface of the through holes 7 of the cooling block 3 to the penetrating object is excessively large, the uniformity in the temperature distribution of the heater 2 is also reduced. The reason for this is that even when the container 1 is sealed, the convection is inevitably generated in the container. As a result, the gas ascends the inside of the through holes of the cooling block and makes contact with the heater. Incidentally, FIG. 3 shows a state when the cooling block is separated from the heater.

When the container 1 is sealed as shown in FIG. 3 and the pressure inside the container is reduced or the container is evacuated with a vacuum pump, the convection of the gas is nearly prevented. Even under this condition, if the distance from the inner surface of the through holes 7 of the cooling block 3 to the penetrating object is excessively large, the uniformity in the temperature distribution of the heater 2 is also reduced. This is caused by the heat dissipation due to radiation. Infrared rays radiated from the heater 2 arrive at the cooling block. They are reflected there to return to the heater 2 without being noticeably absorbed or scattered at the portion other than the through holes of the cooling block. On the other hand, most of the rays having entered the through holes are absorbed while they are repeatedly reflected at the inside of the through holes without returning to the heater. Consequently, the amount of heat dissipation due to the radiation becomes greater at the portion of the surface of the heater close to the through holes of the cooling block than at the portion remote from the through holes. As a result, the temperature at the portion close to the through holes becomes lower than that at the other portion.

On the other hand, when the cooling block makes contact with the heater to cool it, the cooling rate is lower at the heater's portion facing the through holes of the cooling block than at the other portion, which makes contact with the cooling block. Consequently, the temperature remains high at the heater's portion in the vicinity of the portion facing the through holes of the cooling block. As a result, the uniformity in the temperature distribution of the heater is reduced.

As explained above, without regard to whether the cooling block is in contact with the heater or separated from it and whether the container is sealed or not, if the distance from the inner surface of the through holes 7 of the cooling block 3 to the penetrating object is excessively large, the uniformity in the temperature distribution of the heater 2 is reduced. After an intensive study, the present inventors found that when the distance from the inner surface of the through holes of the cooling block to the penetrating object is maintained at most 50 mm, high uniformity in the temperature distribution of the heater can be achieved.

Conversely, if the distance from the inner surface of the through holes 7 of the cooling block 3 to the penetrating object is excessively small, the uniformity in the temperature distribution of the heater 2 is reduced. This is caused by the phenomenon that the heat of the heater 2 is transferred to the cooling block through the penetrating objects, such as the electrodes and temperature-measuring means, at the through holes of the cooling block. As a result, the temperature of the heater is decreased at the portion in the vicinity of the portion to which the electrodes and temperature-measuring means are connected.

When the distance from the inner surface of the through holes 7 of the cooling block 3 to the penetrating object is excessively small, the effect on the uniformity in the temperature distribution of the heater is smaller than that when the distance is excessively large. However, this effect can be a cause of a significant problem in an application where high uniformity in the temperature distribution is required. Therefore, it is undesirable to have an excessively small distance from the inner surface of the through holes 7 of the cooling block 3 to the penetrating object. The present inventors found that it is desirable that the distance be at least 0.1 mm.

As explained above, when the distance from the inner surface of the through holes 7 of the cooling block 3 to the penetrating object is at least 0.1 mm and at most 50 mm, a semiconductor-producing apparatus can be produced that can be used in a wide range of application. For an application that requires a particularly high uniformity in the temperature distribution, it is desirable that the distance be at least 0.2 mm and at most 20 mm. When the range of the distance is reduced to at least 0.2 mm and at most 10 mm, a further increased uniformity can be achieved.

For an application that requires high uniformity in the temperature distribution of the heater at the time of cooling, the use of a cooling block made of a material having a thermal conductivity of at least 30 W/mK increases the uniformity in the temperature distribution of the cooling block. Consequently, the heater is cooled uniformly. As a result, the uniformity in the temperature distribution of the heater at the time of cooling can be increased. For an application that requires a further increased uniformity, it is desirable to use a material having a thermal conductivity of at least 100 W/mK.

A cooling medium may be fed into the cooling block. The cooling block may have in it a flowing path for feeding a cooling medium so that the cooling medium can be fed as required. It is desirable that the cooling system be operated as follows. When the temperature of the heater is raised or the heater's high temperature is maintained, the feeding of the cooling medium is stopped to prevent the temperature-rising rate from decreasing and to reduce the power consumption. The cooling medium is fed only when the heater is cooled. For the sake of handling, it is desirable that the cooling medium be a liquid.

A cooling block having no flowing path for feeding a cooling medium has an upper limit in the thermal capacity. Consequently, when the heater is continuously cooled, the cooling efficiency may decrease gradually. In contrast, a cooling block that uses a cooling medium for cooling can continuously cool the heater without decreasing the cooling efficiency. However, the cooling block having a flowing path for feeding a cooling medium to cool the heater has a complicated structure in itself. In addition, it requires a unit for circulating and cooling the cooling medium. Whether or not to use the cooling medium can be determined as appropriate by considering the above-described features.

It is desirable that the heater of the present invention be made of a ceramic material. It is undesirable to use a metal because it poses a problem of adhesion of particles on the wafer. When prime importance is placed on the uniformity in the temperature distribution, it is desirable that the ceramic material be aluminum nitride or silicon carbide, which has high thermal conductivity. When prime importance is placed on the reliability, it is desirable that the ceramic material be silicon nitride, which has high strength and is strong against heat shock. When prime importance is placed on the cost, it is desirable that the ceramic material be aluminum oxide.

Of these ceramic materials, in consideration of the balance between the performance and cost, it is desirable to use aluminum nitride (AlN). The method of producing the heater of the present invention is explained in detail below when AlN is used as an example.

It is desirable that the material powder of AlN have a specific surface area of 2.0 to 5.0 m²/g. If the specific surface area is less than 2.0 m²/g, the ability of the aluminum nitride to be sintered is decreased. If the specific surface area is more than 5.0 m²/g, the coagulation of the powder becomes extremely intense, rendering the handling difficult. In addition, it is desirable that the material powder have an oxygen content of at most 2 wt. %. If the oxygen content is more than 2 wt. %, the thermal conductivity of the sintered body is decreased. In addition, it is desirable that the amount of metallic impurities other than aluminum included in the material powder be at most 2,000 ppm. If the amount of metallic impurities exceeds this limit, the thermal conductivity of the sintered body is decreased. In particular, it is desirable that the content of each of the IV-group element, such as Si, and the iron-group element, such as Fe, be at most 500 ppm, because they are highly active in reducing the thermal conductivity of the sintered body as metallic impurities.

Because the ability of AlN to be sintered is low, it is desirable that a sintering agent be added to the material powder of the AlN. It is desirable that the sintering agent to be added be a rare-earth element compound. During the sintering, a rare-earth element compound reacts with aluminum oxide or aluminum oxynitride existing on the surface of the particles of the aluminum nitride powder. This reaction not only promotes the aluminum nitride to become compact but also is active in removing oxygen, which causes a decrease in the thermal conductivity of the aluminum nitride sintered body. As a result, the thermal conductivity of the aluminum nitride sintered body can be increased.

It is particularly desirable that the rare-earth element compound be a yttrium compound, which is noticeably active in removing oxygen. It is desirable that the added amount be 0.01 to 5 wt. %. If the amount is less than 0.01 wt. %, not only is it difficult to obtain a compact sintered body but also the thermal conductivity of the sintered body decreases. If the amount is more than 5 wt. %, the sintering agent is allowed to be present at grain boundaries of the aluminum nitride sintered body. Consequently, when the sintered body is used in a corrosive atmosphere, the sintering agent existing in the grain boundaries is etched, causing the falling-off of grains and the production of particles. It is more desirable that the added amount of the sintering agent be at most 1 wt. %. When the amount is at most 1 wt. %, the triple point of the grain boundaries becomes free from the sintering agent, improving the anti-corrosion property. The applicable rare-earth element compound may be in the form of an oxide, a nitride, a fluoride, a stearate compound, and the like. Of these compounds, it is desirable to use an oxide, because it is low-cost and easily available. When the aluminum nitride material powder, a sintering agent, and other ingredients are mixed by using an organic solvent, it is particularly desirable to use a stearate compound, because it has high affinity with an organic solvent and therefore increases the mixability.

Next, predetermined amounts of solvent and binder and, as required, a dispersant and a deflocculant are added to the aluminum nitride material powder and the sintering-agent powder, and they are all mixed. The mixing may be performed by using the ball-mill mixing method, the ultrasonic mixing method, or the like. This mixing produces a material slurry.

The obtained slurry is then formed and sintered to obtain an aluminum nitride sintered body. The applicable method for the foregoing process is classified into two types: the cofiring process and the postmetallizing process.

First, the postmetallizing process is explained below. The slurry is processed by using a spray dryer or another method to produce granules. The granules are placed into a specific mold to perform the press molding. At this moment, it is desirable that the pressure for the pressing operation be at least 9.8 MPa. If the pressure is less than 9.8 MPa, the formed body cannot have enough strength in many cases and it tends to fracture by handling.

It is desirable that the formed body have a density of at least 1.5 g/cm³, depending on the content of the binder and the added amount of the sintering agent. If the density is less than 1.5 g/cm³, the distance between the particles of the material powder becomes relatively large, rendering it difficult for the sintering to proceed. In addition, it is desirable that the formed body have a density of at most 2.5 g/cm³. If the density is more than 2.5 g/cm³, it becomes difficult to remove the binder in the formed body sufficiently in the next step of a degreasing treatment. As a result, it becomes difficult to obtain a compact sintered body as described above.

Next, the formed body is heated in a nonoxidizing atmosphere to perform a degreasing treatment. If the degreasing treatment is performed in an oxidizing atmospheric gas such as air, the surface of the AlN powder is oxidized, thereby decreasing the thermal conductivity of the sintered body. It is desirable that the nonoxidizing atmospheric gas be nitrogen or argon. It is desirable that the degreasing treatment be performed at a heating temperature of at least 500° C. and at most 1,000° C. If the temperature is less than 500° C., the binder cannot be removed sufficiently. Consequently, carbon remains excessively in the formed body after the degreasing treatment, hindering the sintering in the subsequent sintering step. If the temperature is more than 1,000° C., the amount of the remaining carbon becomes excessively small. This reduces the ability to remove the oxygen in the oxide film on the surface of the AlN powder, and therefore the thermal conductivity of the sintered body is decreased.

It is desirable that the amount of carbon remaining in the formed body after the degreasing treatment be at most 1.0 wt. %. If the carbon remains in excess of 1.0 wt. %, the carbon hinders the sintering and a compact sintered body cannot be obtained.

Next, sintering is performed. The sintering is conducted in a nonoxidizing atmospheric gas such as nitrogen or argon and at a temperature of 1,700 to 2,000° C. At this moment, it is desirable that the water vapor contained in the atmospheric gas used, such as nitrogen, be at most −30° C. when expressed as the dew point. If the water vapor is contained in excess of this limit, the AlN reacts with the water vapor in the atmospheric gas at the time of sintering. This reaction forms an oxynitride, and consequently the thermal conductivity may be decreased. In addition, it is desirable that the oxygen content in the atmospheric gas be at most 0.001 vol. %. If the oxygen content is high, the surface of the AlN is oxidized and consequently the thermal conductivity may be decreased.

Furthermore, it is desirable that the jig to be used at the time of sintering be produced by using a boron nitride (BN) formed body. A BN formed body not only has sufficient heat resistance at the above-described sintering temperature but also has good solid lubrication quality at the surface. Consequently, it can reduce the friction between the jig and the AlN sintered body when the AlN sintered body shrinks at the time of sintering. As a result, a sintered body having less strain can be obtained.

The obtained sintered body is processed as required. When a conductive paste is to be screen-printed in the next step, it is desirable that the sintered body have a surface roughness, Ra, of at most 5 μm. If the roughness is more than 5 μm, when an electric circuit is formed by screen-printing, defects such as smearing of the pattern and pinholes tend to occur. It is more desirable that the surface roughness, Ra, be at most 1 μm.

When the surface is polished to achieve the foregoing surface roughness, even when one surface only is to be screen-printed, it is recommended that not only the surface to be screen-printed but also the opposite surface be polished (when both surfaces of the sintered body are to be screen-printed, the both surfaces are polished as a matter of course). If only the surface to be screen-printed is polished, the surface without being polished has to support the sintered body at the time of screen-printing. In this case, the surface without being polished may have a protrusion or a foreign matter. If that is the case, the support of the sintered body becomes unstable and, as a result, the screen-printing may fail to delineate the circuit pattern satisfactorily.

In this case, it is desirable that the two polished surfaces have a parallelization degree of at most 0.5 mm. If the degree is more than 0.5 mm, the variation in the thickness of the conductive paste may increase at the time of screen-printing. It is particularly desirable that the degree be at most 0.1 mm. In addition, it is desirable that the surface to be screen-printed have a flatness of at most 0.5 mm. If the flatness is more than 0.5 mm, the variation in the thickness of the conductive paste may also increase. It is particularly desirable that the flatness be at most 0.1 mm.

A conductive paste is applied to the polished sintered body by screen-printing to form an electric circuit. The conductive paste can be obtained by mixing a metal powder, a binder, a solvent, and, as required, an oxide powder. It is desirable that the metal for the metal powder be tungsten, molybdenum, or tantalum, in consideration of the matching in the coefficient of thermal expansion with that of the ceramic material.

An oxide powder may be added to the conductive paste to increase the bonding strength with the AlN. It is desirable that the oxide for the oxide powder be an oxide of the IIa- or IIIa-group element, Al₂O₃, SiO₂, or the like. It is particularly desirable to use yttrium oxide, because it has excellent wettability with AlN. It is desirable that the added amount of the oxide be 0.1 to 30 wt. %. If the amount is less than 0.1 wt. %, the bonding strength between the metallic layer forming the electric circuit and the AlN decreases. If the amount is more than 30 wt. %, the metallic layer forming the electric circuit increases its electric resistance.

It is desirable that the conductive paste have a thickness of at least 5 μm and at most 100 μm after it is dried. If the thickness is less than 5 μm, not only does the electric resistance excessively increase but also the bonding strength decreases. If the thickness is more than 100 μm, the bonding strength also decreases.

When the circuit pattern to be formed is the heater circuit (circuit of the heat-generating element), it is desirable that the spacing between adjacent pattern elements be at least 0.1 mm. If the spacing is less than 0.1 mm, when an electric current is fed into the heat-generating element, a leakage current may flow depending on the applied voltage and temperature, causing a short circuit. In particular, when the circuit is used at a temperature of 500° C. or higher, it is desirable that the spacing be at least 1 mm, more desirably at least 3 mm.

Subsequently, the printed conductive paste is degreased and then baked. The degreasing is carried out in a nonoxidizing atmospheric gas such as nitrogen or argon. It is desirable that the degreasing temperature be at least 500° C. If the temperature is less than 500° C., the removal of the binder in the conductive paste becomes insufficient, so that carbon remains in the metallic layer. Consequently, when the conductive paste is baked, the carbon forms a carbide of the metal, increasing the electric resistance of the metallic layer.

It is desirable that the baking be performed in a nonoxidizing atmospheric gas such as nitrogen or argon and at a temperature of at least 1,500° C. If the temperature is less than 1,500° C., the grain growth of the metal powder in the conductive paste does not proceed properly and, as a result, the electric resistance of the metallic layer after the baking increases excessively. In addition, it is recommended that the baking temperature be not higher than the sintering temperature of the ceramic material. If the conductive paste is baked at a temperature higher than the sintering temperature of the ceramic material, the sintering agent and other constituents contained in the ceramic material begin to volatilize. Furthermore, the grain growth of the metal powder in the conductive paste is promoted. As a result, the bonding strength between the metallic layer and the ceramic material is decreased.

Next, an insulating coating may be formed on the metallic layer to secure the insulation of the formed metallic layer. The material of the insulating coating has no specific limitation providing that it has little reactivity with the electric circuit and has a difference in the coefficient of thermal expansion with the AlN as small as at most 5.0×10⁻⁶/K. For example, a material such as crystallized glass or AlN can be used. The insulating coating can be formed through the following process, for example. The material is prepared in the form of paste. The paste is screen-printed with a predetermined thickness. Degreasing is conducted as required. The coating is baked at a predetermined temperature to complete the process.

Furthermore, a ceramic plate may be laminated, as required, with the AlN sintered body provided with the electric circuit protected by the insulating coating. It is recommended that the lamination be carried out through a bonding material. The bonding material is produced by adding a IIa-group element compound and/or a IIIa-group element compound, a binder, and a solvent to an aluminum oxide powder and/or an aluminum nitride powder. The bonding material is then prepared in the form of paste and applied to the bonding surface by screen-printing or another appropriate method. The thickness of the applied bonding material has no specific limitation. Nevertheless, it is desirable that the thickness be at least 5 μm. If the thickness is less than 5 μm, the bonding layer tends to have a bonding defect such as pinholes and bonding unevenness.

The ceramic plate coated with a bonding material is degreased in a nonoxidizing atmosphere and at a temperature of at least 500° C. Subsequently, the ceramic plate to be laminated is piled up with the foregoing AlN sintered body and a predetermined load is applied to them. Under this condition, they are heated in a nonoxidizing atmosphere, so that they are bonded with each other. It is desirable that the load be at least 5 kPa. If the load is less than 5 kPa, either a sufficient bonding strength cannot be achieved or the above-described bonding defect tends to occur.

The heating temperature for the bonding has no specific limitation providing that the temperature is sufficiently high for satisfactorily bonding the ceramic plate with the foregoing AlN sintered body through the bonding layer. Nevertheless, it is desirable that the temperature be at least 1,500° C. If the temperature is less than 1,500° C., it is difficult to achieve sufficient bonding strength and therefore a bonding defect tends to occur. It is desirable that the nonoxidizing atmospheric gas at the time of the degreasing and bonding be nitrogen or argon.

The above-described process can produce a ceramic-laminated sintered body to be used as a heater. Incidentally, the electric circuit can be formed without using a conductive paste. For example, a heater circuit can be formed by using a molybdenum wire (coil), and an electrode for an electrostatic chuck, an RF electrode, and the like can be formed by using a molybdenum or tungsten mesh.

In this case, the electric circuit and the electrodes can be formed by embedding the foregoing molybdenum coil or mesh in the AlN material powder and hot-pressing them. The temperature and atmosphere for the hot pressing may be in accordance with the sintering temperature and atmosphere for the above-described AlN. However, it is desirable that the hot-pressing pressure be at least 0.98 MPa. If the pressure is less than 0.98 MPa, a gap may be produced between the molybdenum coil or mesh and the AlN. When this occurs, the heater may fail to perform satisfactorily.

Next, the cofiring method is explained below. The above-described material slurry is formed into a sheet by the doctor blade method. The sheet formation has no specific limitation. Nevertheless, it is desirable that the sheet have a thickness of at most 3 mm after it is dried. If the thickness is more than 3 mm, the slurry increases the amount of shrinkage due to drying. As a result, the probability is increased that the sheet develops cracks.

A metallic layer forming an electric circuit having a predetermined pattern is formed by applying a conductive paste onto the above-described sheet by the screen-printing method or another proper method. The same conductive paste as explained in the postmetallizing method may also be used in this method. However, in the cofiring method, a conductive paste without containing an oxide powder can be used without any problem.

Next, a sheet having a formed circuit and a sheet having no formed circuit are laminated with each other. The lamination is performed by placing the sheets at a predetermined position to pile up them. At this moment, if required, a solvent is applied to the surface facing the other one. The piled-up sheets are heated as required. When heating is conducted, it is desirable that the heating temperature be at most 150° C. If the heating is conducted at a temperature exceeding this limit, the laminated sheets deform considerably. Then a pressure is applied to the piled-up sheets to unify them. It is desirable that the applied pressure be in the range of 1 to 100 MPa. If the pressure is less than 1 MPa, the sheets may fail to be consolidated sufficiently. If this occurs, the sheets may separate from each other in the following steps. If the pressure is more than 100 MPa, the amount of the deformation of the sheets becomes excessively large.

The laminated body is degreased and sintered as in the above-described postmetallizing method. The temperature for the degreasing and sintering, the amount of carbon, and other conditions are the same as in the postmetallizing method. In the above-described step for printing a conductive paste on the sheet, when a heater circuit, an electrode for an electrostatic chuck, and the like are printed on each of a plurality of sheets and then the sheets are laminated with at least one sheet having no formed circuit, an electric heater having a plurality of electric circuits can be easily produced. Thus, a ceramic-laminated sintered body to be used as a heater can be obtained.

When the electric circuits such as the heat-generating circuit are formed on the uppermost layer and/or the undermost layer of the ceramic-laminated body and exposed, an insulating coating may be formed on the electric circuits as in the above-described postmetallizing method to protect the electric circuits and to secure the insulation.

The obtained ceramic-laminated sintered body is machined as required. Usually, the sintered body under the as-sintered condition fails in many cases to meet the precision required for the use in a semiconductor-producing apparatus. The desirable machining precision is as follows. For example, it is desirable that the surface for placing an object to be treated have a flatness of at most 0.5 mm, particularly desirably at most 0.1 mm. If the flatness is more than 0.5 mm, a gap tends to be produced between the object being treated and the ceramic heater. When the gap is produced, the heat from the ceramic heater cannot be uniformly transferred to the object being treated and the temperature unevenness tends to occur in the object being treated.

In addition, it is desirable that the surface for placing an object to be treated have a surface roughness, Ra, of at most 5 μm. If “Ra” is more than 5 μm, the friction between the heater generating heat and the object being treated may increase the falling-off of AlN grains. When this occurs, the fallen grains become particles and will adversely affect the treatment such as the film formation and etching onto the object being treated. It is more desirable that the surface roughness, Ra, be at most 1 μm.

### EXAMPLE 1

An aluminum nitride sintered body was produced by the following process. First, 100 weight parts of aluminum nitride powder and 0.6 weight parts of yttrium stearate powder were mixed. Next, 10 weight parts of polyvinyl butyral as a binder and 5 weight parts of dibutyl phthalate as a solvent were mixed into the foregoing mixed powder. The resultant mixed material was processed by the spray-drying method to produce granules. The granules were press-formed and degreased in a nitrogen atmosphere at 700° C. The formed body was sintered in a nitrogen atmosphere at 1,850° C. to complete the process. The aluminum nitride powder used had an average particle diameter of 0.6 μm and a specific surface area of 3.4 m²/g. The produced aluminum nitride sintered body was machined so as to have a diameter of 330 mm and a thickness of 15 mm.

A tungsten paste was produced by using 100 weight parts of tungsten powder having an average particle diameter of 2.0 μm, one weight part of Y₂O₃, five weight parts of ethyl cellulose as a binder, and butyl carbitol as a solvent. The mixing of the materials was performed by using a pot mill provided with three rollers. A circuit pattern of the heating element was formed by applying the tungsten paste onto the foregoing aluminum nitride sintered body by screen-printing. Then, the circuit pattern was degreased in a nitrogen atmosphere at 900° C. and baked in a nitrogen atmosphere at 1,800° C. A ZnO—B₂O₃—Al₂O₃-based glass paste was applied with a thickness of 100 μm to the surface on which the circuit pattern of the heating element was formed, except current-feeding portions. The glass paste was baked in a nitrogen atmosphere at 700° C. Tungsten terminals were attached to the current-feeding portions through gold solder. Nickel electrodes were screw-fixed to the tungsten terminals to complete the production of the heater.

Next, a cooling block was produced by using two pure-aluminum plates having a diameter of 330 mm. One plate had a thickness of 12 mm, and the other 7 mm. The pure-aluminum plates had a thermal conductivity of 200 W/mK. A coolant-flowing path having a width of 5 mm and a depth of 5 mm was formed by machining in the aluminum plate having a thickness of 12 mm. A groove having a width of 2 mm and a depth of 1 mm for housing an O-ring was formed at the outside of the flowing path. Through holes were formed at the entrance and exit for the cooling medium. The two aluminum plates were combined with the O-ring placed in the groove, and they were fixed with screws. The aluminum plates were provided with three through holes for the current-feeding electrodes and the thermocouple to penetrate.

The heater and cooling block were installed in a container of a semiconductor-producing apparatus having a specified shape. Current-feeding electrodes and a thermocouple were attached to the heater through the through holes of the cooling block. Thus, the heater became ready for heating by current feeding. The container of the semiconductor-producing apparatus was the sealed type shown in FIG. 3.

Seven types of cooling blocks were prepared that had different distances, L, from the inner surface of the through hole of the cooling block to the current-feeding electrode or thermocouple as shown in Table I. After the temperature of the heater was raised to 400° C. when measured by the thermocouple, the temperature, 400° C., was maintained for 30 minutes to achieve temperature stabilization. Then, the temperature variation, ΔT₁, in the heater was measured. During this period, the cooling block was separated from the heater without feeding the cooling medium.

Subsequently, the current feeding was stopped. The cooling block to which water as the cooling medium was fed was brought into contact with the heater to cool it. After the heater temperature reached 200° C., the temperature variation, ΔT₂, in the heater was measured. These results are shown in Table I.

The measurement of the temperature variation was conducted by using a wafer provided with a temperature-measuring means. This temperature-measuring wafer was placed on the surface of the heater for placing a wafer to be treated. The difference between the maximum value and the minimum value measured with the temperature-measuring wafer was used as the temperature variation in the heater. The cooling rate of the heater was 28° C./min for all cases. When the cooling was performed without bringing the cooling block into contact with the heater, the cooling rate was as low as 9° C./min.

TABLE I

| No. | L (mm) | ΔT₁ (° C.) | ΔT₂ (° C.) |
|---|---|---|---|
| 1 | 0.08 | 3.4 | 7.0 |
| 2 | 0.12 | 1.8 | 3.7 |
| 3 | 0.2 | 1.5 | 3.1 |
| 4 | 10.0 | 1.6 | 3.3 |
| 5 | 20.0 | 1.9 | 4.1 |
| 6 | 45.0 | 2.1 | 4.5 |
| 7 | 60.0 | 3.9 | 8.3 |

As can be seen from Table I, No. 2 to 6 heaters of the present invention showed a small temperature variation whether the heater temperature was maintained with the cooling block being separated from the heater or the heater was cooled with the cooling block being in contact with the heater. In other words, these heaters had excellent uniformity in temperature distribution. As explained above, in the present invention, when the heater was made of aluminum nitride, it was possible that the temperature distribution of the heater was within +0.4% (0.8% in the width of variation) when the temperature of the heater was maintained at 400° C. Furthermore, it was possible that the temperature distribution at the time of cooling was within +1.5% (3% in the width of variation).

### EXAMPLE 2

Five types of cooling blocks were prepared that were made of different materials as shown in Table II. They had a distance of 0.5 mm from the inner surface of the through hole of the cooling block to the penetrating object such as the electrode or thermocouple. The conditions other than the material of the cooling block, such as the heater and the coolant-flowing path, were the same as in Example 1. The temperature variation in the heater was measured at 400° C. and 200° C. The results are shown in Table II. The thermal conductivity of the material of the cooling block is also shown in Table II.

TABLE II

| | | Thermal | | |
|---|---|---|---|---|
| | | conductivity | | |
| No. | Material of cooling block | (W/mK) | ΔT₁ (° C.) | ΔT₂ (° C.) |
| 8 | Nickel-chromium steel | 17 | 4.1 | 8.5 |
| 9 | Nickel steel | 30 | 2.4 | 5.0 |
| 10 | Pure iron | 75 | 2.4 | 4.9 |
| 11 | Cast aluminum | 100 | 1.6 | 3.2 |
| 12 | Pure aluminum | 200 | 1.5 | 3.1 |

As can be seen from Table II, when the thermal conductivity of the material of the cooling block was increased to 30 W/mK or more, the uniformity of the temperature distribution of the heater was significantly improved. Furthermore, when the thermal conductivity was further increased to 100 W/mK or more, the uniformity was further improved.

### EXAMPLE 3

Three types of heaters were produced with different materials through a method similar to that used in Example 1. They were made of aluminum oxide, silicon carbide, and silicon nitride. The heater made of aluminum nitride produced in Example 1 was also used in this example. That is, four types of heaters were used in total. The distance from the inner surface of the through hole of the cooling block to the penetrating object such as the electrode or thermocouple was 0.5 mm. The material of the cooling block was pure aluminum. As with Example 1, the temperature variation in the heater was measured at 400° C. and 200° C.

In addition, after the temperature of the heater was raised to 400° C. when measured by the thermocouple, the temperature, 400° C., was maintained for 30 minutes to achieve temperature stabilization. Then, the current feeding was stopped. The cooling block to which cooling water was fed was brought into contact with the heater to cool it to 50° C. The temperature was raised again as before. This cycle was repeated 1,000 times at the maximum to find the number of cycles at which the heater was broken. These results are shown in Table III.

TABLE III

| | | | | Number of cycles |
|---|---|---|---|---|
| | | | | at which the |
| No. | Material of heater | ΔT₁ (° C.) | ΔT₂ (° C.) | heater was broken |
| 12 | Aluminum nitride | 1.5 | 3.1 | Not broken |
| 13 | Aluminum oxide | 8.0 | 15.7 | 897 |
| 14 | Silicon carbide | 2.5 | 4.9 | Not broken |
| 15 | Silicon nitride | 7.1 | 13.8 | Not broken |

Note:
No. 12 of this table and No. 12 of Table II are the same sample.

As can be seen from Table III, aluminum nitride and silicon carbide have excellent uniformity in temperature. The materials other than aluminum oxide were not broken in the heat cycle test, proving that they have high reliability. It was found that aluminum nitride not only has excellent uniformity in temperature but also has high reliability.

The present invention enables the production of a semiconductor-producing apparatus provided with a heater that has not only a dramatically increased cooling rate, which is achieved by bringing the cooling block into contact with the heater when the heater is cooled, but also an excellent uniformity in temperature distribution. Consequently, when the semiconductor-producing apparatus of the present invention is applied to the following various semiconductor-producing apparatuses, the apparatuses can have a sufficient temperature distribution: an etching device, a sputtering device, a plasma CVD unit, a reduced-pressure plasma CVD unit, a metal CVD unit, an insulating-film CVD unit, a low-dielectric-constant-film CVD unit, an MOCVD unit, a degasifier, an ion implanter, a coater-developer, and so on.

1. A semiconductor-producing apparatus comprising:
(a) a heater for heat-treating a semiconductor wafer; and
(b) a cooling block for cooling the heater;
the cooling block being provided with at least one through hole for inserting a penetrating object;
the distance from the inner surface of the or each through hole to the penetrating object being at most 50 mm.

2. A semiconductor-producing apparatus as defined by claim 1, wherein the distance from the inner surface of the or each through hole to the penetrating object is at least 0.1 mm.

3. A semiconductor-producing apparatus as defined by claim 1, wherein the cooling block is made of a material having a thermal conductivity of at least 30 W/mK.

4. A semiconductor-producing apparatus as defined by claim 1, wherein the cooling block is made of a material having a thermal conductivity of at least 100 W/mK.

5. A semiconductor-producing apparatus as defined by claim 1, wherein the heater's major constituent is any one of aluminum nitride, aluminum oxide, silicon carbide, and silicon nitride.

6. A semiconductor-producing apparatus as defined by claim 1, wherein the heater's major constituent is aluminum nitride.
